(19) United States
(12) Patent Application Publication
(10) Pub. No.: US 2016/0057370 A1
(43) Pub. Date: Feb. 25, 2016

(54) SOLID-STATE IMAGING DEVICE

(71) Applicant: OLYMPUS CORPORATION, Tokyo (JP)

(72) Inventor: Takanori Tanaka, Tokyo (JP)

(73) Assignee: OLYMPUS CORPORATION, Tokyo (JP)

(21) Appl. No.: 14/933,658

(22) Filed: Nov. 5, 2015

Related U.S. Application Data
(63) Continuation of application No. PCT/JP2014/062238, filed on May 7, 2014.

(30) Foreign Application Priority Data
May 8, 2013 (JP) 2013-098723

(51) Int. Cl. H04N 5/378; H04N 5/63; H04N 5/376

(52) U.S. Cl. CPC H04N 5/378; H04N 5/3765; H04N 5/63

(57) ABSTRACT

A solid-state imaging device includes a pixel unit, a reference signal generation unit including current sources, and analog-to-digital (A/D) conversion units. The A/D conversion units include comparators and counters. Each of the A/D conversion units includes at least one of the comparators and at least one of the counters which are lined up in a column direction of the pixel unit. The current sources are lined up in a row direction of the pixel unit, and face the comparators of the A/D conversion units in the column direction of the pixel unit. The comparators of the A/D conversion units are arranged between the current sources and the counters of the A/D conversion units.

This application is a continuation application based on PCT Patent Application No. PCT/JP2014/062238, filed on May 7, 2014, whose priority is claimed on Japanese Patent Application No. 2013-098723, filed on May 8, 2013. The contents of both the Japanese Application and the PCT Application are incorporated herein by reference.

### BACKGROUND OF THE INVENTION

1. Field of the Invention

The present invention relates to a solid-state imaging device used in a digital camera, a digital video camera, an endoscope, or the like.

2. Description of Related Art

As a means for analog-to-digital (A/D) converting a pixel signal read out from a pixel and implementing high-speed readout of the pixel signal, a column A/D conversion-type solid-state imaging device is known (for example, see Japanese Unexamined Patent Application, First Publication No. 2005-323331). FIG. 8 shows a constitution identical to the constitution of a solid-state imaging device disclosed in Japanese Unexamined Patent Application, First Publication No. 2005-323331.

The solid-state imaging device shown in FIG. 8 has a pixel unit 1000, a vertical scanning circuit 1002, a horizontal scanning circuit 1003, a timing control unit 1004, a reference signal generation unit 1005, A/D conversion units 1006, and an output unit 1007. The pixel unit 1000 has a plurality of pixels 1001 arranged in a matrix form. The pixels 1001 have photoelectric conversion elements that convert incident light into electrical signals, generate pixel signals, and output the generated pixel signals to vertical signal lines VTL arranged for respective pixel columns. The reference signal generation unit 1005 generates a ramp signal RAMP that is a reference signal whose voltage value linearly increases or decreases over time.

The A/D conversion units 1006 constitute so-called single-slope A/D conversion circuits (SSADCs), and have comparators 1013 and counters 1014. A comparator 1013 and a counter 1014 which are included in each of the A/D conversion units 1006 are lined up in a column direction (a vertical direction, a longitudinal direction in FIG. 8) of the pixel unit 1000. The A/D conversion units 1006 are arranged for respective pixel columns, and lined up in a row direction (a horizontal direction, a lateral direction in FIG. 8) of the pixel unit 1000.

The comparators 1013 compare the ramp signal RAMP generated by the reference signal generation unit 1005 with pixel signals read out from the pixels 1001, and generate pulse signals having pulse widths corresponding to the magnitudes of the pixel signals based on the comparison results. During time periods in accordance with the pulse signals generated by the comparators 1013, the counters 1014 count count clocks CNTCLK whose frequency is known, thereby converting the pulse widths of the pulse signals into count values. Also, the counters 1014 hold digital signals based on the count values, and output the held digital signals to a horizontal signal transmission line HTL arranged in the row direction in accordance with horizontal transmission control signals H1 to H4 generated by the horizontal scanning circuit 1003.

The vertical scanning circuit 1002 controls operation of the pixels 1001. The horizontal scanning circuit 1003 generates the horizontal transmission control signals H1 to H4 for outputting the digital signals held by the counters 1014 to the horizontal signal transmission line HTL. The output unit 1007 is composed of, for example, a sense amplifier, buffers the signals output to the horizontal signal transmission line HTL, and outputs the signals as imaging signals. The timing control unit 1004 generates the count clock CNTCLK which is a clock for controlling the reference signal generation unit 1005 and a clock counted by the counters 1014. Also, the timing control unit 1004 generates a control signal for controlling operation of the vertical scanning circuit 1002 and the horizontal scanning circuit 1003.

In the reference signal generation unit 1005, for example, a digital-to-analog conversion circuit (DAC) is used. FIG. 9 shows an example of a constitution of a reference signal generation unit 1005a composed of a DAC. The reference signal generation unit 1005a has a current source cell unit 1010, a shift register 1011, and a resistance 1012.

The current source cell unit 1010 has a plurality of current source cells 1015 arranged in a matrix form. In the example shown in the drawing, the number of rows of a matrix consisting of the plurality of current source cells 1015 is i, and the number of columns is j. The shift register 1011 outputs a selection signal SEL to the current source cell unit 1010 in synchronization with the count clock CNTCLK, and sequentially selects current source cells 1015 outputting a current. The resistance 1012 converts a current flowing to the current source cell unit 1010 into a voltage. One end of the resistance 1012 is connected to a reference voltage source which supplies a reference voltage VREF, and the other end of the resistance 1012 is connected to the current source cell unit 1010. The ramp signal RAMP is output from the other end of the resistance 1012.

FIG. 10 shows an example of a constitution of a current source cell 1015. The current source cell 1015 has a current source 1016 and switches 1017 and 1018. The current source 1016 flows a constant current (a current value: IREF). The switches 1017 and 1018 are switches that change a path in which the constant current flows. One end of the switch 1017 is connected to an output terminal that outputs the ramp signal RAMP, and the other end of the switch 1017 is connected to one end of the current source 1016. One end of the switch 1018 is connected to the reference voltage source that supplies the reference voltage VREF, and the other end of the switch 1018 is connected to the end of the current source 1016. Switching between on and off of the switch 1017 is controlled by the selection signal SEL, and switching between on and off of the switch 1018 is controlled by an inversion signal xSEL obtained by inverting the selection signal SEL.

When the selection signal SEL is high, the inversion signal xSEL is low. At this time, the switch 1017 is turned on, and the switch 1018 is turned off, so that the constant current flows to the resistance 1012. When the selection signal SEL is low, the inversion signal xSEL is high. At this time, the switch 1017 is turned off, and the switch 1018 is turned on, so that a current flows from the reference voltage source. For this reason, the current source 1016 keeps the current flowing at all times. Due to this, immediately after the selection signal SEL becomes high, the current source cell 1015 can provide a stable current flow.

FIG. 11 shows operation of the reference signal generation unit 1005a. In FIG. 11, waveforms of the count clock CNTCLK and the selection signal SEL and a current value IRAMP and a voltage value VRAMP of the ramp signal RAMP are shown. The horizontal axis of FIG. 11 is time, and the vertical axis of FIG. 11 is voltage or current.

Operation of the reference signal generation unit 1005a will be described below. When the count clock CNTCLK is input to the shift register 1011, the shift register 1011 outputs a selection signal SEL(m, n) (here, 1≦m≦i, 1≦n≦j) in synchronization with rising or falling of the count clock CNTCLK (falling in the example shown in the drawing), and sequentially selects the current source cells 1015.

At this time, every time one current source cell 1015 is selected, the current value IRAMP flowing to the resistance 1012 is increased by the current value IREF [A] output by the one current source cell 1015. For this reason, when a resistance value of the resistance 1012 is RREF, the voltage value VRAMP of the ramp signal RAMP is reduced by IREF×RRED [V]. By repeating this operation, the reference signal generation unit 1005a generates a ramp signal whose voltage value is changed from VREF [V] to (VREF−i×j×IREF×RREF) [V] in synchronization with the count clock CNTCLK. For example, when the current source cells 1015 are arranged in 16 rows and 16 columns, RREF=51 [Ω], and IREF=76.6 [μA], it is possible to generate a ramp signal which has a resolution of 8 bits (16×16) and whose amplitude is 1 V.

Not only a DAC but also, for example, an integrator circuit can constitute the reference signal generation unit 1005. FIG. 12 shows an example of a constitution of the reference signal generation unit 1005b composed of an integrator circuit having a capacitance. The reference signal generation unit 1005b has a current source 1016, a capacitance 1019, and switches 1020 and 1021. The current source 1016 flows a constant current. The switch 1020 is a switch that resets the capacitance 1019. The switch 1021 is a switch that connects the capacitance 1019 and the current source 1016. One end of the switch 1020 is connected to the reference voltage source which supplies the reference voltage VREF, and the other end of the switch 1020 is connected to one end of the capacitance 1019. One end of the switch 1021 is connected to the one end of the capacitance 1019 and the other end of the switch 1020, and the other end of the switch 1021 is connected to one end of the current source 1016. Switching between on and off of the switch 1020 is controlled by a reset signal RST, and switching between on and off of the switch 1021 is controlled by a start signal ST.

FIG. 13 shows operation of the reference signal generation unit 1005b. In FIG. 13, waveforms of the reset signal RST and the start signal ST and the voltage value VRAMP of the ramp signal RAMP are shown. The horizontal axis of FIG. 13 is time, and the vertical axis of FIG. 13 is voltage.

First, the reset signal RST becomes high, so that the switch 1020 is turned on. Due to this, the capacitance 1019 is reset, and the voltage value VRAMP of the ramp signal RAMP becomes VREF. Subsequently, the reset signal RST becomes low, so that the switch 1020 is turned off.

Subsequently, the start signal ST becomes high, so that the switch 1021 is turned on. Due to this, the current source 1016 and the capacitance 1019 are connected. When a certain time t elapses after a point in time at which the current source 1016 and the capacitance 1019 are connected, charge accumulated in the capacitance 1019 is discharged by IREF×t [C] (t: time). For this reason, the voltage value VRAMP of the ramp signal RAMP is reduced by IREF×t/CREF [V]. At this time, IREF is uniform, and thus the slope of the voltage value VRAMP of the ramp signal RAMP is linear during the time t. For example, when CREF=10 [pF] and IREF=1 [mA], it is possible to generate a ramp signal whose amplitude is changed by 1 V in a time of 10 μsec.

### SUMMARY OF THE INVENTION

According to a first aspect of the present invention, a solid-state imaging device includes: a pixel unit which includes photoelectric conversion elements and in which a plurality of pixels outputting pixel signals are arranged in a matrix form; a reference signal generation unit which includes a plurality of current sources and which is configured to generate a reference signal that is increased or reduced over time; and a plurality of analog-to-digital (A/D) conversion units each of which is arranged for one column or a plurality of columns of the pixel unit, and which are lined up in a row direction of the pixel unit. The plurality of A/D conversion units include: comparators configured to compare the reference signal with the pixel signals; and counters configured to count count clocks during time periods corresponding to magnitudes of the pixel signals based on comparison results by the comparators. Each of the plurality of A/D conversion units includes at least one of the comparators and at least one of the counters, wherein the at least one of the comparators and the at least one of the counters are lined up in a column direction of the pixel unit. At least some of the plurality of current sources are lined up in the row direction of the pixel unit, and face the comparators of the plurality of A/D conversion units in the column direction of the pixel unit. The comparators of the plurality of A/D conversion units are arranged between the plurality of current sources and the counters of the plurality of A/D conversion units.

According to a second aspect of the present invention, in the solid-state imaging device according to the first aspect of the present invention, the plurality of current sources may be arranged in an area, and a width of the area in the row direction of the pixel unit may be smaller than a width of the area in the column direction of the pixel unit.

According to a third aspect of the present invention, in the solid-state imaging device according to the first aspect of the present invention, the reference signal generation unit may include a selection circuit which is constructed by connecting in series a plurality of delay circuits delaying input signals in synchronization with the count clocks and outputting delayed signals and which is configured to select the plurality of current sources. The plurality of delay circuits may be lined up in the row direction of the pixel unit, and face at least some of the plurality of current sources in the column direction of the pixel unit. The comparators of the plurality of A/D conversion units may be arranged between the plurality of current sources and the counters of the plurality of A/D conversion units and between the plurality of delay circuits and the counters of the plurality of A/D conversion units.

According to a fourth aspect of the present invention, in the solid-state imaging device according to the first aspect of the present invention, the reference signal generation unit may be an integrator circuit including the plurality of current sources and a plurality of capacitances. At least some of the plurality of current sources and at least some of the plurality of capacitances may be lined up in the row direction of the pixel unit, and face the comparators of the plurality of A/D conversion units in the column direction of the pixel unit. The comparators of the plurality of A/D conversion units may be arranged between the plurality of current sources and the counters of the plurality of A/D conversion units and between the plurality of capacitances and the counters of the plurality of A/D conversion units.

According to a fifth aspect of the present invention, in the solid-state imaging device according to the fourth aspect of the present invention, during generation of the reference signal, the plurality of current sources may be connected in parallel, and the plurality of capacitances may be connected in parallel.

According to a sixth aspect of the present invention, the solid-state imaging device according to any one of the first to fifth aspects of the present invention may further include: a first substrate: a second substrate; and a connection unit which connects the first substrate and the second substrate. The pixel unit may be arranged in the first substrate. The reference signal generation unit and the plurality of A/D conversion units may be arranged in the second substrate. The connection unit may include a plurality of bumps transmitting the pixel signals to the plurality of A/D conversion units.

According to a seventh aspect of the present invention, in the solid-state imaging device according to the sixth aspect of the present invention, the plurality of bumps may be arranged between the reference signal generation unit and the plurality of A/D conversion units.

### BRIEF DESCRIPTION OF THE DRAWINGS

FIG. 1 is a block diagram showing a constitution of a solid-state imaging device according to a first embodiment of the present invention.

FIG. 2 is a block diagram showing a constitution of a reference signal generation unit according to the first embodiment of the present invention.

FIG. 3 is a block diagram showing a constitution of a reference signal generation unit according to the first embodiment of the present invention.

FIG. 4 is a circuit diagram showing a constitution of a reference signal generation unit according to a second embodiment of the present invention.

FIG. 5 is a block diagram showing a constitution of a solid-state imaging device according to a third embodiment of the present invention.

FIG. 6 is a cross-sectional view showing a cross-sectional structure around a connection unit of the solid-state imaging device according to the third embodiment of the present invention.

FIG. 7 is a block diagram showing a constitution of a solid-state imaging device according to a fourth embodiment of the present invention.

FIG. 8 is a block diagram showing a constitution of an existing solid-state imaging device.

FIG. 9 is a block diagram showing a constitution of an existing reference signal generation unit.

FIG. 10 is a circuit diagram showing a configuration of an existing current source cell.

FIG. 11 is a timing chart showing operation of an existing reference signal generation unit.

FIG. 12 is a circuit diagram showing a constitution of an existing reference signal generation unit.

FIG. 13 is a timing chart showing operation of an existing reference signal generation unit.

### DETAILED DESCRIPTION OF THE INVENTION

Hereinafter, embodiments of the present invention will be described with reference to the drawings.

### First Embodiment

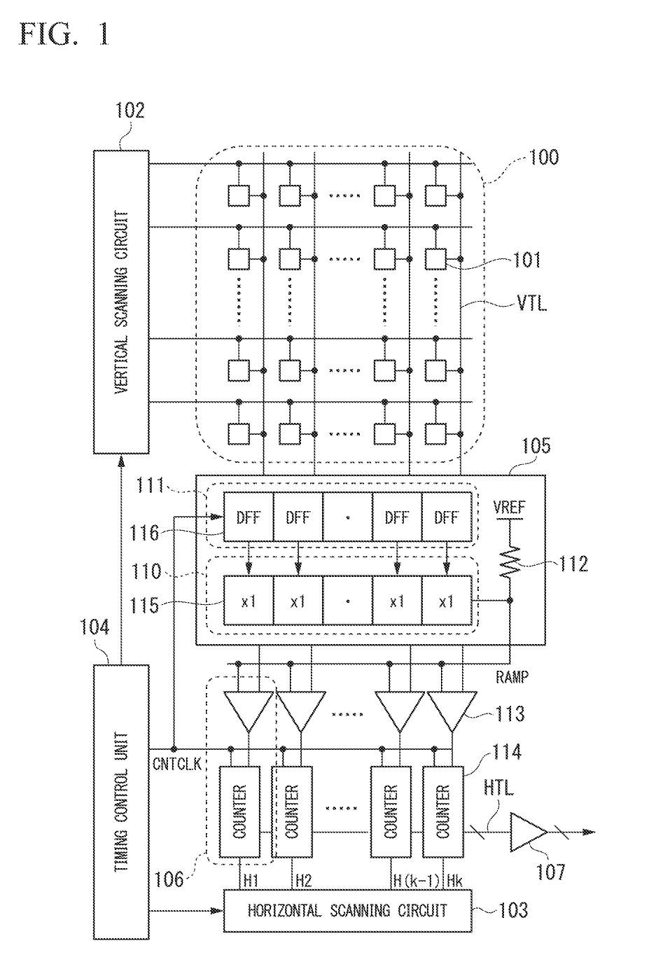

First, a first embodiment of the present invention will be described. FIG. 1 shows a constitution of a solid-state imaging device according to this embodiment.

The solid-state imaging device shown in FIG. 1 has a pixel unit 100, a vertical scanning circuit 102, a horizontal scanning circuit 103, a timing control unit 104, a reference signal generation unit 105, analog-to-digital (A/D) conversion units 106, and an output unit 107. The pixel unit 100 has a plurality of pixels 101 arranged in a matrix form. The pixels 101 have photoelectric conversion elements converting incident light into electrical signals, generate pixel signals, and output the generated pixel signals to vertical signal lines VTL arranged for respective pixel columns. The reference signal generation unit 105 generates a ramp signal RAMP that is a reference signal whose voltage value is linearly increased or reduced over time.

The A/D conversion units 106 constitute so-called single-slope A/D conversion circuits (SSADCs), and have comparators 113 and counters 114. A comparator 113 and a counter 114 which are included in each of the A/D conversion units 106 are lined up in a column direction (a vertical direction, a longitudinal direction in FIG. 1) of the pixel unit 100. The A/D conversion units 106 are arranged for respective pixel columns, and lined up in a row direction (a horizontal direction, a lateral direction in FIG. 1) of the pixel unit 100.

The A/D conversion units 106 are arranged for every column of the pixel unit 100, but the A/D conversion units 106 may be arranged for every plurality of columns. When the A/D conversion units 106 are arranged for every plurality of columns, pixel signals output from pixels 101 of a plurality of different columns are time-divisionally input to one A/D conversion unit 106, and A/D conversion is performed by the A/D conversion unit 106.

The comparators 113 compare the ramp signal RAMP generated by the reference signal generation unit 105 and pixel signals read out from the pixels 101, and generate pulse signals having pulse widths corresponding to the magnitudes of the pixel signals based on the comparison results. During time periods in accordance with the pulse signals generated by the comparators 113, the counters 114 count count clocks CNTCLK whose frequency is known, thereby converting the pulse widths of the pulse signals into count values. Also, the counters 114 hold digital signals based on the count values, and output the held digital signals to a horizontal signal transmission line HTL arranged in the row direction in accordance with horizontal transmission control signals H1 to Hk (k: the number of columns) generated by the horizontal scanning circuit 103.

The vertical scanning circuit 102 controls operation of the pixels 101. The horizontal scanning circuit 103 generates the horizontal transmission control signals H1 to Hk for outputting the digital signals held by the counters 114 to the horizontal signal transmission line HTL. The output unit 107 is composed of for example, a sense amplifier, buffers the signals output to the horizontal signal transmission line HTL, and outputs the signals as imaging signals. The timing control unit 104 generates the count clock CNTCLK which is a clock for controlling the reference signal generation unit 105 and a clock counted by the counters 114. Also, the timing control unit 104 generates a control signal for controlling operation of the vertical scanning circuit 102 and the horizontal scanning circuit 103.

The reference signal generation unit 105 is composed of a digital-to-analog conversion circuit (DAC), and has a current source cell unit 110, a shift register 111, and a resistance 112. The current source cell unit 110 has a plurality of current source cells 115 arranged in the row direction. The shift register 111 outputs a selection signal to the current source cell unit 110 in synchronization with the count clock CNTCLK, and sequentially selects current source cells 115 outputting a current. The resistance 112 converts a current flowing to the current source cell unit 110 into a voltage. One end of the resistance 112 is connected to a reference voltage source which supplies a reference voltage VREF, and the other end of the resistance 112 is connected to the current source cell unit 110. The ramp signal RAMP is output from the other end of the resistance 112.

The shift register 111 constituting a selection circuit which selects the plurality of current source cells 115 is constructed by connecting a plurality of delay circuits 116 (D flip-flops in the example shown in the drawing) in series. The count clock CNTCLK is input to the leftmost delay circuit 116. The leftmost delay circuit 116 delays the input count clock CNTCLK and outputs the delayed count clock. The remaining delay circuits 116 delay signals output from delay circuits 116 adjacent to the left and output the delayed signals. Due to this, the plurality of delay circuits 116 operate in synchronization with the count clock CNTCLK.

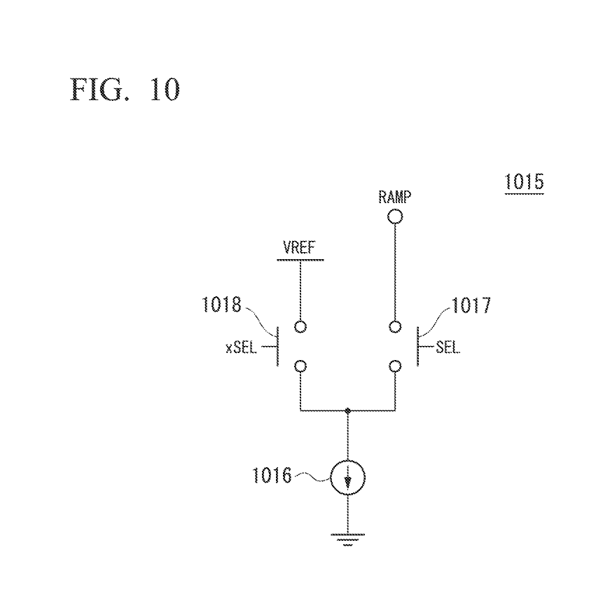

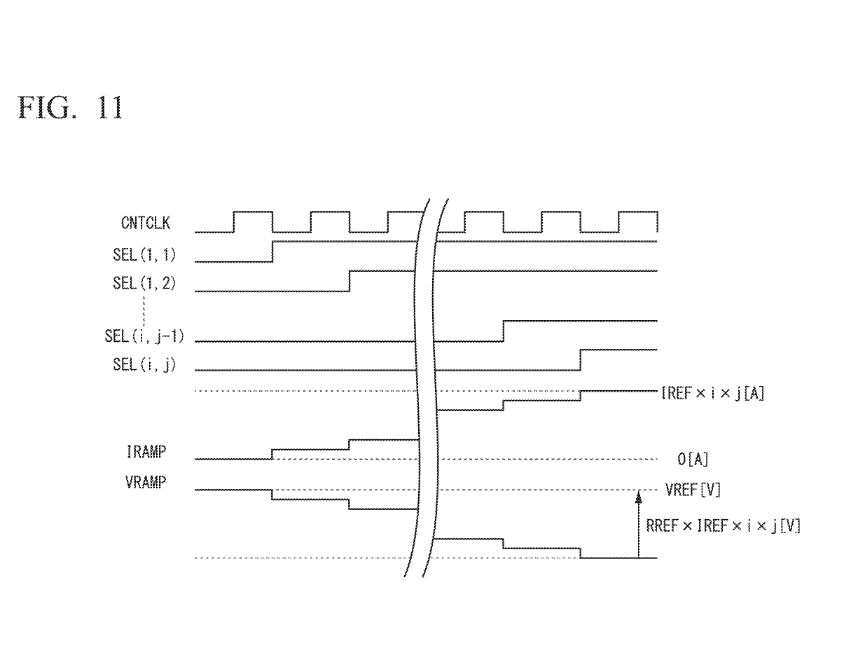

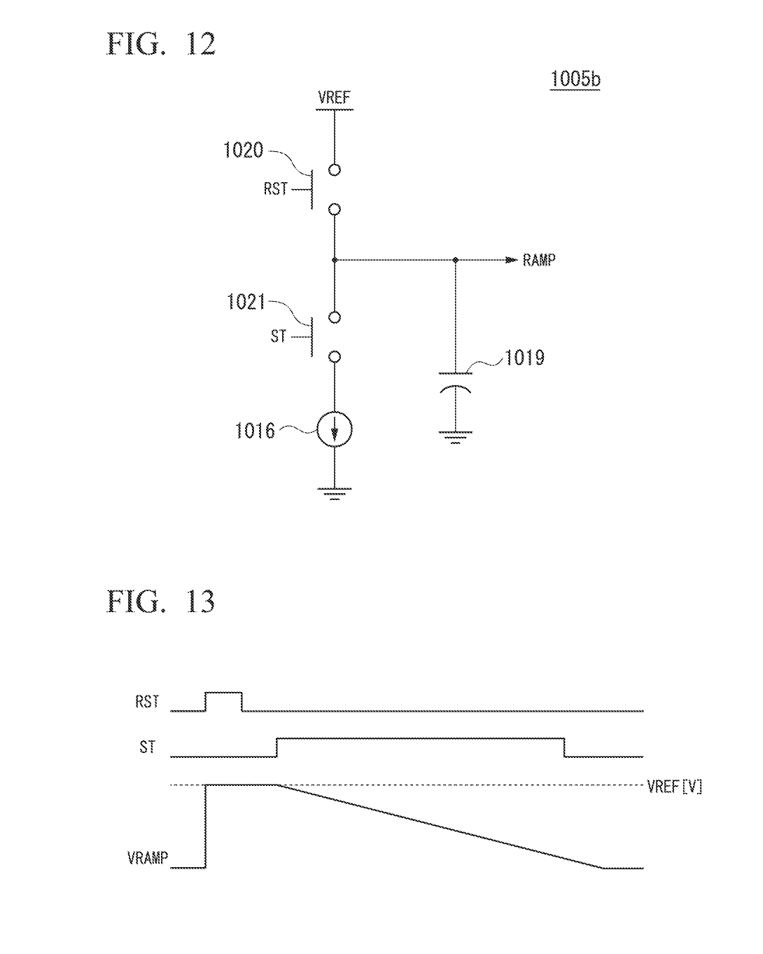

A constitution of the current source cells 115 is the same as, for example, the constitution of the current source cell 1015 shown in FIG. 10. Also, operation of the reference signal generation unit 105 is the same as the operation shown in FIG. 11, and thus the description of operation of the reference signal generation unit 105 will be omitted.

In the column direction, the reference signal generation unit 105 faces the plurality of A/D conversion units 106 which are lined up in the row direction. More specifically, the plurality of current source cells 115 constituting the current source cell unit 110 of the reference signal generation unit 105 face the plurality of A/D conversion units 106 in the column direction. The plurality of current source cells 115 constituting the current source cell unit 110 and the plurality of delay circuits 116 constituting the shift register 111 are lined up in the row direction.

The plurality of current source cells 115 of the reference signal generation unit 105, the plurality of comparators 113 of the plurality of A/D conversion units 106, and the plurality of counters 114 of the plurality of A/D conversion units 106 are lined up in the column direction in that order. In other words, the plurality of comparators 113 of the plurality of A/D conversion units 106 are arranged between the plurality of current source cells 115 of the reference signal generation unit 105 and the plurality of counters 114 of the plurality of A/D conversion units 106.

Also, the pixel unit 100, the reference signal generation unit 105, and the plurality of A/D conversion units 106 are lined up in the column direction in that order. In other words, the reference signal generation unit 105 is arranged between the pixel unit 100 and the plurality of A/D conversion units 106.

The reference signal generation unit 105 and the vertical signal lines VTL are formed in different layers. For example, the reference signal generation unit 105 is formed in a layer above another layer in which the vertical signal lines VTL are formed.

As stated above, the plurality of current source cells 115 constituting the current source cell unit 110 and the plurality of delay circuits 116 constituting the shift register 111 are arranged in the row direction in a distributed manner. In the example shown in the drawing, one current source cell 115 and one delay circuit 116 are arranged for every column of the pixel unit 100. For this reason, it is possible to arrange the reference signal generation unit 105 between the pixel unit 100 and the comparators 113 to face the comparators 113. Accordingly, it is possible to reduce the horizontal width of the solid-state imaging device (the width of the solid-state imaging device in the row direction of the pixel unit 100).

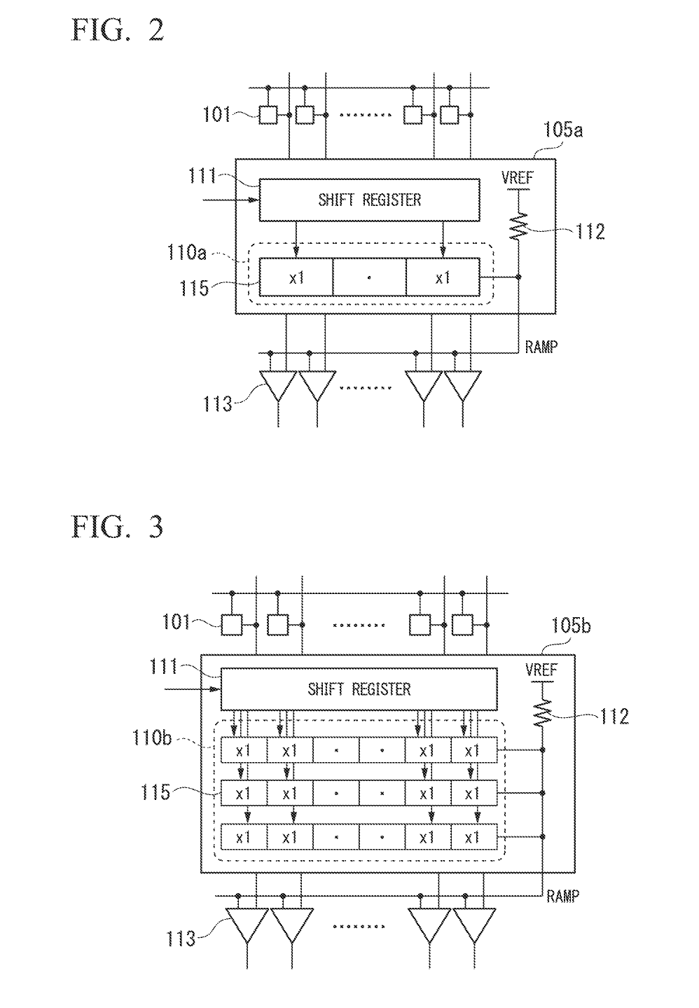

An arrangement form of the current source cells 115 is not limited to the form in FIG. 1. FIG. 2 and FIG. 3 show other arrangement forms of the current source cells 115. In a current source cell unit 110a of a reference signal generation unit 105a shown in FIG. 2, one current source cell 115 is arranged for every plurality of columns (two columns in the example shown in the drawing) of the pixel unit 100. One current source cell 115 may be arranged for every three or more columns. Also, current source cells 115 may be arranged in a ratio of q current source cells 115 (q≧2) to p columns (p≧2) of the pixel unit 100. In a current source cell unit 110b of a reference signal generation unit 105b shown in FIG. 3, current source cells 115 are arranged over a plurality of rows (three rows in the example shown in the drawing). Current source cells 115 may be arranged over two rows, or may be arranged over four or more rows.

For example, when the current source cells 115 are arranged in a matrix form as shown in FIG. 3, it is preferable to reduce a width of the reference signal generation unit 105 in the column direction. To this end, it is preferable for a width (vertical width) of the current source cell unit 110 in the column direction to be smaller than a width (horizontal width) of the current source cell unit 110 in the row direction. In other words, it is preferable for the column direction width of an area in which the plurality of current source cells 115 are arranged to be smaller than the row direction width of the area in which the plurality of current source cells 115 are arranged.

In the example of this embodiment, the width of the current source cell unit 110 in the row direction is approximately the same as the width of the pixel unit 100 in the row direction. Also, the location of the leftmost current source cell 115 of the current source cell unit 110 is almost the same as the location of the leftmost pixel 101 of the pixel unit 100, and the location of the rightmost current source cell 115 of the current source cell unit 110 is almost the same as the location of the rightmost pixel 101 of the pixel unit 100.

The width of the current source cell unit 110 in the row direction may be larger than the width of the pixel unit 100 in the row direction. Also, the location of the leftmost current source cell 115 of the current source cell unit 110 may be further to the left than the location of the leftmost pixel 101 of the pixel unit 100, and the location of the rightmost current source cell 115 of the current source cell unit 110 may be further to the right than the location of the rightmost pixel 101 of the pixel unit 100. However, in order to suppress an increase in the horizontal width of the solid-state imaging device, it is preferable for a ratio of the horizontal width of a portion of the current source cell unit 110 arranged further to the right or left than the location of the leftmost or rightmost pixel 101 of the pixel unit 100 to the whole horizontal width of the current source cell unit 110 to be, for example, 20% or less.

As described above, according to this embodiment, at least some of the plurality of current source cells 115 are lined up in the row direction of the pixel unit 100, and also face the plurality of comparators 113 of the plurality of A/D conversion units 106 in the column direction of the pixel unit 100. Therefore, it is possible to reduce the width of the solid-state imaging device in the row direction of the pixel unit 100.

### Second Embodiment

Next, a second embodiment of the present invention will be described. A constitution of a solid-state imaging device according to the second embodiment is the same as the constitution of the solid-state imaging device according to the first embodiment except for a constitution of a reference signal generation unit.

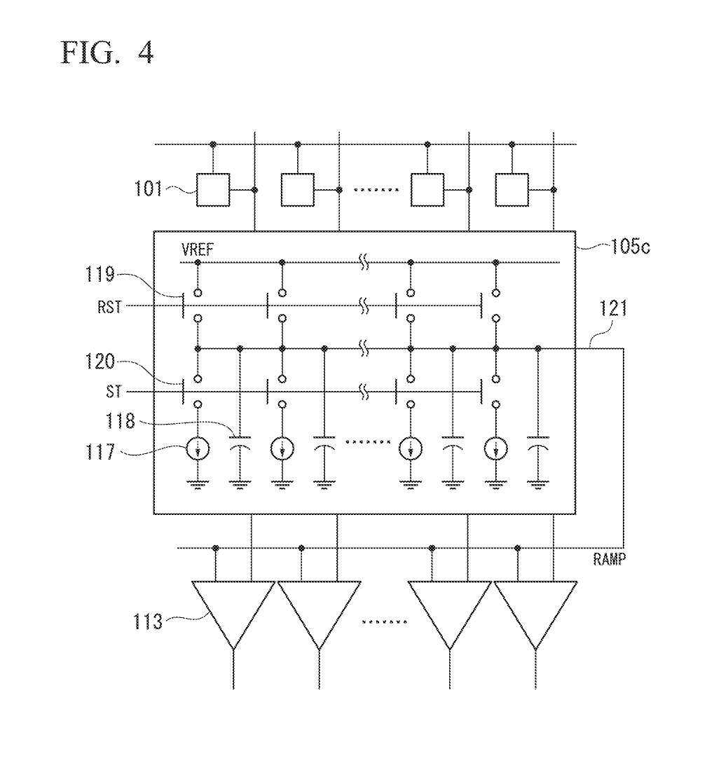

A reference signal generation unit according to the second embodiment is composed of an integrator circuit having a capacitance. FIG. 4 shows a constitution of a reference signal generation unit 105c according to the second embodiment. The reference signal generation unit 105c has a plurality of current sources 117, a plurality of capacitances 118, and a plurality of switches 119 and 120.

The current sources 117 flow constant currents. One end of each of the capacitances 118 is connected to a ramp signal line 121 arranged in the row direction. The switches 119 are switches that reset the capacitances 118. The switches 120 are switches that connect the capacitances 118 to the current sources 117. One end of each of the switches 119 is connected in common to a reference voltage source which supplies a reference voltage VREF, and the other end of each of the switches 119 is connected to the ramp signal line 121. One end of each of the switches 120 is connected to the other ends of the switches 119 and the ramp signal line 121, and the other end of each of the switches 120 is connected to one end of the corresponding current source 117. Switching between on and off of the switches 119 is controlled by a reset signal RST, and switching between on and off of the switches 120 is controlled by a start signal ST.

In the column direction, the reference signal generation unit 105c faces the plurality of A/D conversion units 106 which are lined up in the row direction. More specifically, the current sources 117 and the capacitances 118 constituting the reference signal generation unit 105c face the plurality of A/D conversion units 106 in the column direction. The plurality of current sources 117 and the plurality of capacitances 118 constituting a plurality of reference signal generation units 105c are lined up in the row direction. Also, the current sources 117 and the capacitances 118 are alternately lined up.

The plurality of current sources 117 and the plurality of capacitances 118 of the reference signal generation unit 105c, the plurality of comparators 113 of the plurality of A/D conversion units 106, and the plurality of counters 114 of the plurality of A/D conversion units 106 are lined up in the column direction in that order. In other words, the plurality of comparators 113 of the plurality of A/D conversion units 106 are arranged between the plurality of current sources 117 and the plurality of capacitances 118 of the reference signal generation unit 105c and the plurality of counters 114 of the plurality of A/D conversion units 106.

Also, the pixel unit 100, the reference signal generation unit 105c, and the plurality of A/D conversion units 106 are lined up in the column direction in that order. In other words, the reference signal generation unit 105c is arranged between the pixel unit 100 and the plurality of A/D conversion units 106.

Operation of the reference signal generation unit 105c is the same as operation shown in FIG. 13 except that there are plural sets of a current source, a capacitance, and two types of switches, and thus the description of operation of the reference signal generation unit 105c will be omitted.

In the constitution shown in FIG. 4, the plurality of capacitances 118 are connected in parallel, and constitute one large capacitance. Further, when the start signal ST becomes high during generation of the ramp signal RAMP, the switches 120 are turned on, so that the plurality of current sources 117 are connected in parallel to constitute one large current source. Due to this, it is possible to flow a current having the same magnitude as an existing current.

As stated above, the plurality of current sources 117 and the plurality of capacitances 118 are arranged in the row direction in a distributed manner. In the example shown in the drawing, one current source 117 and one capacitance 118 are arranged for every column of the pixel unit 100. For this reason, it is possible to arrange the reference signal generation unit 105c between the pixel unit 100 and the comparators 113 to face the comparators 113. Accordingly, it is possible to reduce the horizontal width of the solid-state imaging device (the width of the solid-state imaging device in the row direction of the pixel unit 100).

An arrangement form of the current sources 117 and the capacitances 118 is not limited to the form in FIG. 4. For example, one or more current sources 117 and capacitances 118 may be arranged for every plurality of columns of the pixel unit 100. Also, the current sources 117 and the capacitances 118 may be arranged over a plurality of rows.

Conditions of the column direction width (vertical width) and the row direction width (horizontal width) of an area in which the plurality of current sources 117 and the plurality of capacitances 118 are arranged are the same as the conditions of the respective widths of the current source cell unit 110 which have been described in the first embodiment.

As described above, according to this embodiment, at least some of the plurality of current sources 117 and the plurality of capacitances 118 are lined up in the row direction, and also face the plurality of comparators 113 of the plurality of A/D conversion units 106 in the column direction of the pixel unit 100. Therefore, it is possible to reduce the width of the solid-state imaging device in the row direction.

### Third Embodiment

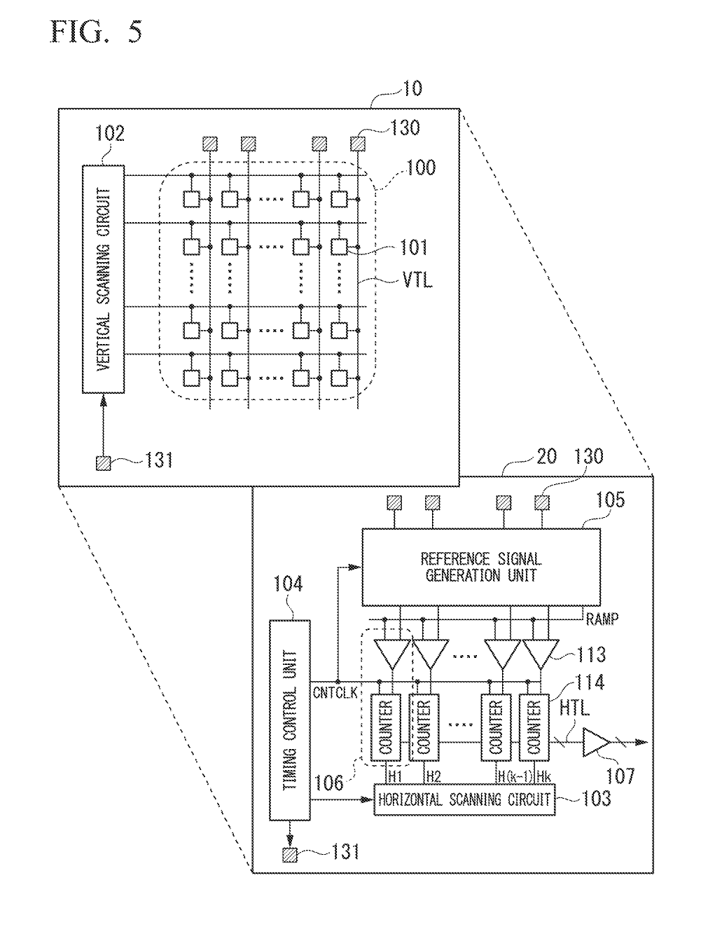

Next, a third embodiment of the present invention will be described. FIG. 5 schematically shows a constitution of a solid-state imaging device according to this embodiment. The solid-state imaging device shown in FIG. 5 has a first substrate 10 and a second substrate 20. The first substrate 10 and the second substrate 20 are stacked with their main surfaces (surfaces having relatively larger surface areas than side surfaces) opposite to each other and joined. In FIG. 5, in order to facilitate understanding of a constitution of the solid-state imaging device, the first substrate 10 and the second substrate 20 are shifted and shown.

The first substrate 10 has a pixel unit 100 and a vertical scanning circuit 102. The second substrate 20 has a horizontal scanning circuit 103, a timing control unit 104, a reference signal generation unit 105, A/D conversion units 106, and an output unit 107. In FIG. 5, like reference signs are given to the same components as those shown in FIG. 1. The reference signal generation unit 105 may be the reference signal generation unit 105a shown in FIG. 2, the reference signal generation unit 105b shown in FIG. 3, the reference signal generation unit 105c shown in FIG. 4, or the like.

The first substrate 10 and the second substrate 20 are connected through a connection unit. The connection unit includes a plurality of bumps 130 and 131. The bumps 130 connect the vertical signal lines VTL which are arranged for respective pixel columns in the first substrate 10 to signal lines which are connected to input terminals of comparators 113 in the second substrate 20, and transmit pixel signals from the first substrate 10 to the second substrate 20 (from the pixel unit 100 to the A/D conversion units 106). The bump 131 transmits a control signal output from the timing control unit 104 of the second substrate 20 to the first substrate 10. The control signal transmitted by the bump 131 is input to the vertical scanning circuit 102 of the first substrate 10.

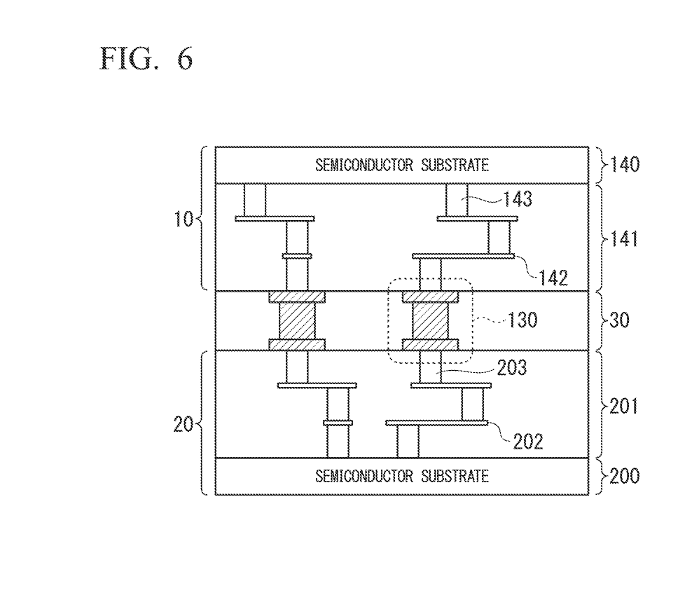

FIG. 6 shows a cross-sectional structure around the connection unit. The first substrate 10 has a semiconductor substrate 140 and a wiring layer 141. The wiring layer 141 has wirings 142 of a plurality of layers and connection layers 143 which connect the wirings 142 of the different layers. The connection layers 143 are formed as vias or contacts. The second substrate 20 has a semiconductor substrate 200 and a wiring layer 201. The wiring layer 201 has wirings 202 of a plurality of layers and connection layers 203 which connect the wirings 202 of the different layers. The connection layers 203 are formed as vias or contacts. A connection unit 30 is arranged between the first substrate 10 and the second substrate 20. The connection unit 30 is composed of the bumps 130. The bumps 130 are connected to the connection layers 143 of the first substrate 10 and the connection layers 203 of the second substrate 20. The bump 131 also has the same structure as stated above.

As described above, according to this embodiment, by providing the first substrate 10 having the pixel unit 100 and the vertical scanning circuit 102 and the second substrate 20 having the other circuits, it is possible to reduce the width of the solid-state imaging device in the row direction and also reduce a width of the solid-state imaging device in the column direction.

### Fourth Embodiment

Next, a fourth embodiment of the present invention will be described. A constitution of a solid-state imaging device according to the fourth embodiment is the same as the constitution of the solid-state imaging device according to the third embodiment except for the locations of bumps 130 which transmit pixel signals from the first substrate 10 to the second substrate 20.

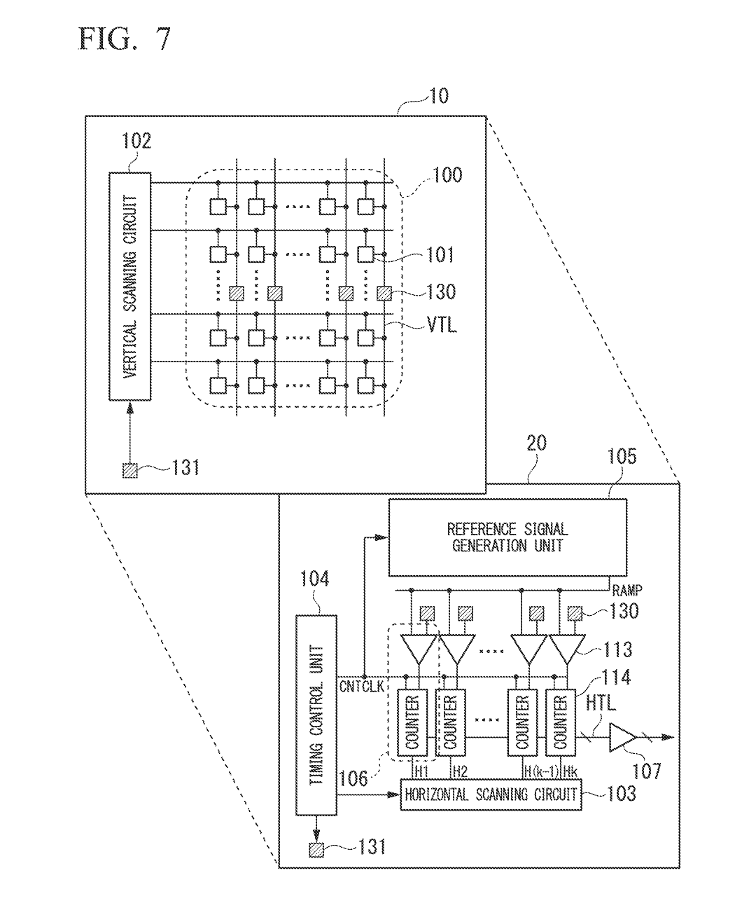

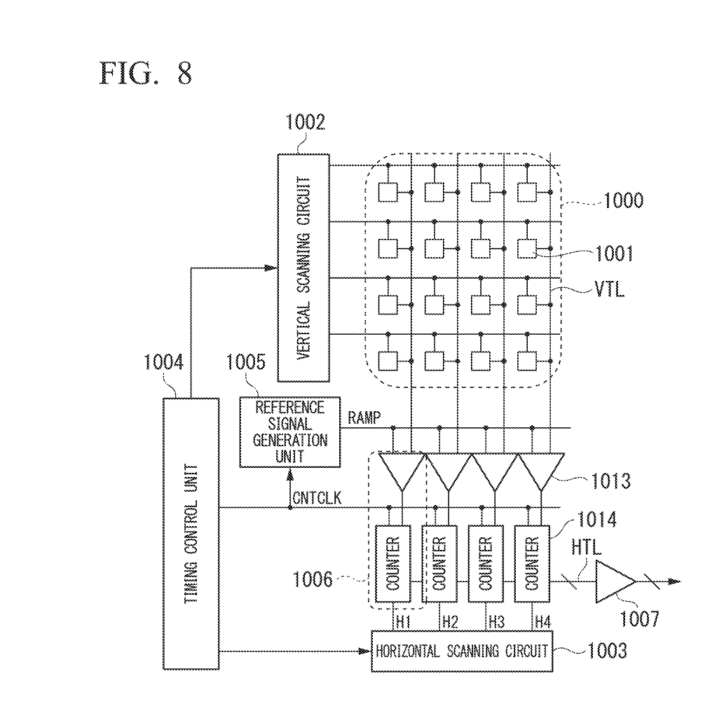

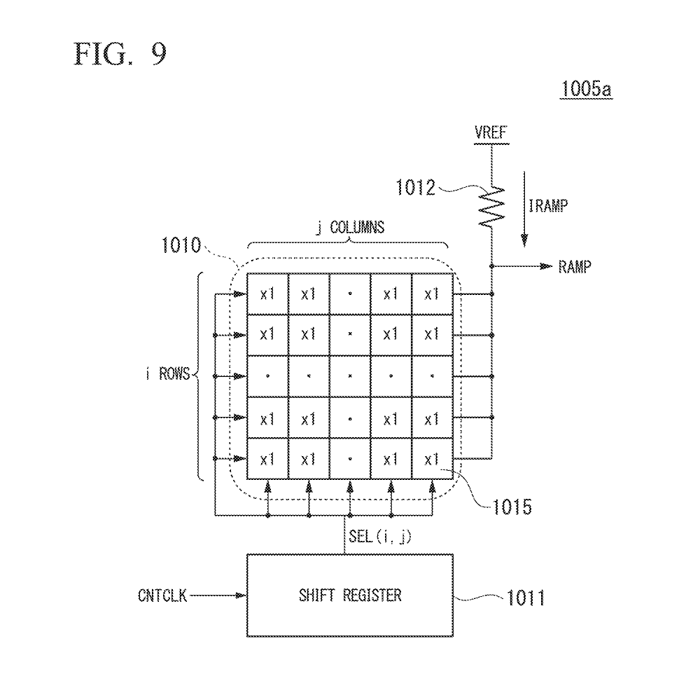

FIG. 7 schematically shows a constitution of a solid-state imaging device according to this embodiment. In FIG. 7, like reference signs are given to the same components as those shown in FIG. 5. In the solid-state imaging device shown in FIG. 7, a plurality of bumps 130 are arranged between the reference signal generation unit 105 and the comparators 113. For this reason, pixel signals output to the second substrate 20 are input to the comparators 113 without passing through the reference signal generation unit 105. Due to this, noise (for example, noise generated by coupling with the ramp signal RAMP, wraparound of digital noise of a shift register of a DAC or the like, and the like) that has been superimposed on pixel signals when the pixel signals pass through the reference signal generation unit 105 in the first to third embodiments disappears.

Accordingly, according to this embodiment, it is possible to obtain the same effects as obtained in the third embodiment and also to obtain an image of a favorable signal-to-noise ratio (S/N).

Thus far, preferable embodiments of the present invention have been described, but the present invention is not limited to these embodiments. Within a range not departing from the spirit and scope of the present invention, addition, omission, replacement, and other changes of components are possible. The present invention is not limited to the foregoing description, and is only limited by the scope of the appended claims.

What is claimed is:

1. A solid-state imaging device comprising:
a pixel unit which includes photoelectric conversion elements and in which a plurality of pixels outputting pixel signals are arranged in a matrix form;
a reference signal generation unit which includes a plurality of current sources and which is configured to generate a reference signal that is increased or reduced over time; and
a plurality of analog-to-digital (A/D) conversion units each of which is arranged for one column or a plurality of columns of the pixel unit, and which are lined up in a row direction of the pixel unit,
wherein the plurality of A/D conversion units include:
comparators configured to compare the reference signal with the pixel signals; and
counters configured to count count clocks during time periods corresponding to magnitudes of the pixel signals based on comparison results by the comparators,
each of the plurality of A/D conversion units includes at least one of the comparators and at least one of the counters, wherein the at least one of the comparators and the at least one of the counters are lined up in a column direction of the pixel unit,
at least some of the plurality of current sources are lined up in the row direction of the pixel unit, and face the comparators of the plurality of A/D conversion units in the column direction of the pixel unit, and
the comparators of the plurality of A/D conversion units are arranged between the plurality of current sources and the counters of the plurality of A/D conversion units.

2. The solid-state imaging device according to claim 1,
wherein the plurality of current sources are arranged in an area, and a width of the area in the row direction of the pixel unit is smaller than a width of the area in the column direction of the pixel unit.

3. The solid-state imaging device according to claim 1,
wherein the reference signal generation unit includes a selection circuit which is constructed by connecting in series a plurality of delay circuits delaying input signals in synchronization with the count clocks and outputting delayed signals and which is configured to select the plurality of current sources,
the plurality of delay circuits are lined up in the row direction of the pixel unit, and face at least some of the plurality of current sources in the column direction of the pixel unit, and
the comparators of the plurality of A/D conversion units are arranged between the plurality of current sources and the counters of the plurality of A/D conversion units and between the plurality of delay circuits and the counters of the plurality of A/D conversion units.

4. The solid-state imaging device according to claim 1,
wherein the reference signal generation unit is an integrator circuit including the plurality of current sources and a plurality of capacitances,
at least some of the plurality of current sources and at least some of the plurality of capacitances are lined up in the row direction of the pixel unit, and face the comparators of the plurality of A/D conversion units in the column direction of the pixel unit, and
the comparators of the plurality of A/D conversion units are arranged between the plurality of current sources and the counters of the plurality of A/D conversion units and between the plurality of capacitances and the counters of the plurality of A/D conversion units.

5. The solid-state imaging device according to claim 4,
wherein, during generation of the reference signal, the plurality of current sources are connected in parallel, and the plurality of capacitances are connected in parallel.

6. The solid-state imaging device according to claim 1, further comprising:
a first substrate:
a second substrate; and
a connection unit which connects the first substrate and the second substrate,
wherein the pixel unit is arranged in the first substrate,
the reference signal generation unit and the plurality of A/D conversion units are arranged in the second substrate, and
the connection unit includes a plurality of bumps transmitting the pixel signals to the plurality of A/D conversion units.

7. The solid-state imaging device according to claim 6,
wherein the plurality of bumps are arranged between the reference signal generation unit and the plurality of A/D conversion units.
